(19) United States
(12) Patent Application Publication
(10) Pub. No.: US 2009/0029270 A1
(43) Pub. Date: Jan. 29, 2009

(54) Projection exposure device and method of separate exposure

(75) Inventors: Akira OTSUKA, Tokyo (JP); Wataru NAKAGAWA, Tokyo (JP); Masaru MORIYA, Tokyo (JP)

Correspondence Address: WEINGARTEN, SCHURGIN, GAGNEBIN & LEBOVICI LLP, TEN POST OFFICE SQUARE, BOSTON, MA, 02109, US

(73) Assignee: ADTEC ENGINEERING CO., LTD., Tokyo (JP)

(21) Appl. No.: 12/178,786

(22) Filed: Jul. 24, 2008

(30) Foreign Application Priority Data
Jul. 27, 2007 (JP) 2007-195879

(51) Int. Cl. G03F 1/00; G03B 27/42

(52) U.S. Cl. 430/5; 355/53

(57) ABSTRACT

A projection exposure device which can perform high accurate alignment and separate exposures wherein the mask marks 20 overlap with the corresponding board marks 30 in exposure, the mask marks 20 are larger than the board marks 30 so as to shield the board marks 30 from the exposing light, and a diameter ØM of the circular mask mark 20 is larger than a diameter ØB of the circular board mark 30.

This application claims priority to Japanese Appln. No. JP 2007-195879 filed Jul. 27, 2007.

### BACKGROUND OF THE INVENTION

This invention relates to a projection exposure device and a method of dividing exposure.

The photolithography method has been applied widely in various fields, wherein a prescribed pattern is photographically imprinted by an exposure device on a surface of a substrate coated with photosensitive materials such as photo resist, thereafter the pattern is formed on the substrate by etching process. Printed circuit boards have also been fabricated by using the exposure device in recent years.

For producing the printed circuit boards, a contact type exposure device is mainly utilized where whole area of a board to be exposed is exposed in one time. However, in a contact type exposure device, it is difficult to comply with the demand for alignment accuracy due to expansion and contraction of a board which is a natural behavior of the material of the printed board. Thus, there is a need for providing exposure by a projection exposure which is relievable for the effect of the expansion and contraction of the board.

In order to enhance productivity, a board design of so-called “multiple areas” to increase the number of the product produced by a single exposure is becoming mainstream. In this case, the dividing exposure is also applied.

In the dividing exposure, a cutting line (a cutting area) between exposure areas (product areas) on the board to be exposed is very narrow, for example in package boards less than 0.5 mm. A board alignment mark (hereinafter referred to as a board mark) used in the dividing exposure is placed in the narrow cutting area.

In this case, the board marks corresponding to each dividing exposure areas may be placed on the above narrow space, but it is not practical. It is common to use the same board mark between the adjacent dividing exposure areas.

The followings are the examples showing the related art.

Laid open No. 2004-12598

Laid open No. 2004-4215

Laid open No. 2006-072100

In the dividing exposure, said cutting area is exposed by the former exposure and the board mark in the cutting area and the periphery of the board mark are discolored by the exposure and a recognition performance of the board mark is decreased, which results in making the accuracy of the next alignment worse.

A mask shatter as disclosed by Japanese Patent Laid-Open No. 2006-072100 is usually provided with a divided type exposure device and a projection exposure device so that only exposing portion, i.e. only the product area is exposed and the cutting area including the board mark is not exposed.

However, it is technically difficult to expose definitely only exposing portion because the cutting area is very narrow and the space between the board mark and the exposing portion is very small, additionally the mask shatter is limited in the alignment accuracy. Thus, the cutting area, at least part of the cutting area including the board mark is also unavoidably exposed when exposing the exposing area.

Thus photosensitive resin covered on said board mark is exposed and the board mark is unavoidable discolored, which make alignment accuracy worse.

The object of the invention is to resolve such problems of the prior art.

### SUMMARY OF THE INVENTION

A projection exposure device of the invention including a light source for irradiating exposure light and a photo mask depicted with a pattern to be exposed on a board as an exposing target and irradiating said pattern of said photo mask to a certain area of the board as the exposing target comprises a mask mark for alignment provided with the photo mask, a board mark for alignment provided with the board, and an alignment device for aligning the photo mask and the board based on the mask mark and the board mark individually photographed thereby. Said mask mark and said board mark are positioned overlapped each other when exposing. Said mask mark is larger than said board mark, and said mask mark shields said board mark from the exposure light.

The device of the invention can prevent the decreasing of the recognition performance of the board mark and alignment accuracy by unintended exposure of photosensitive resin.

In the separate exposure process, said certain area of the board is plural and said irradiation of said pattern of said photo mask is carried out successively against each area of a plurality of said certain area of the board. Said board mark is plural for said plural certain areas and said mask mark is also plural for the plural board marks. At least one or more of the board mark is utilized in common with said plurality of said certain area of the board, and one or more of mask mark corresponding to the board mark utilized in common is larger than the board mark and shields said board mark from the exposure light.

This invention is useful in the alignment method using different photographic devices detecting the mask mark and board mark respectively (as shown in Japan Patent Laid-open No. 2004-4215), and in the alignment method detecting successively the mask mark and the board mark by the same photosensitive device (as shown in Japan Patent Laid-open No. 2004-12598).

This invention cannot be adapted to the method using one photographic device detecting simultaneously both the mask mark and the board mark.

The projection exposure device and the method of dividing exposure of the invention can provide the dividing exposure keeping high alignment accuracy without demand for the high accurate positioning of the mask shutter and without decreasing the number of the final products per one board by widening the cutting area.

### BRIEF DESCRIPTION OF THE DRAWINGS

FIG. 1 is a schematic front view of an embodiment of the invention.

FIG. 2 is a schematic plan view of an embodiment of the mask mark and the board mark.

FIG. 3 is a explanatory view of the shielding operation by the mask mark in an embodiment of the invention.

FIG. 4 is a schematic front section view of an embodiment of the mask mark and the board mark.

FIG. 5 is a schematic front view of an embodiment of the photographic unit 1.

### DETAILED DESCRIPTION OF THE PREFERRED EMBODIMENTS

An embodiment of the invention will now be described in reference to the attached drawings.

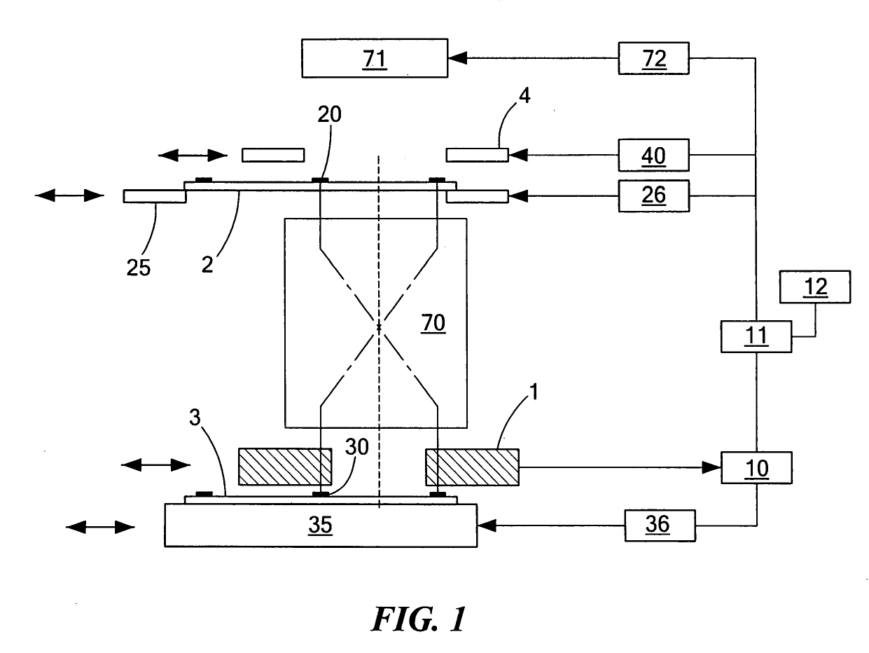

FIG. 1 shows a projection exposure device for producing a printed circuit board. A printed circuit board 3 provided with photo resist layer is placed on a stage 35 that is movable in the XYZ and θ directions by a moving device 36 that is controlled by a controller 11.

A photo mask 2 having patterns, such as circuits to be projected, is positioned facing toward the printed circuit board 3. A projection lens 70 is installed between the photo mask 2 and the printed circuit board 3. The photo mask 2 is supported by a mask stage 25 that is movable to adjust the position of the photo mask 2. The patterns of the photo mask 2 are projected onto the printed circuit board 3 by an exposing light providing, for example, ultraviolet rays, from an exposure light source 71. The mask 2 is projected on the board 3 with expansion or reduction at a predetermined magnification or with the same size as determined by projection exposure lens 70.

In the embodiments described in FIG. 1, the photo mask 2 and the printed circuit board 3 are arranged horizontally one above the other. However, it is also possible to vertically arrange the photo mask 2 and the printed circuit board 3. Further the photo mask 2 may be constructed movable and not the printed circuit board 3. Both the photo mask 2 and the printed circuit board 3 can be adapted to be movable.

A mask mark 20 is provided with the photo mask 2 and a board mark 30 is provided with the printed circuit board 3. An alignment of the photo mask 2 and the printed circuit board 3 is executed by using the mask mark 20 and the board mark 30.

A photographic unit 1 has a CCD camera and an illumination device and is connected to an image processor 10, the controller 11 and a display 12. The details of the photographic unit 1 are described later.

The photographic unit 1 is movable and the moving of the photographic unit 1 is controlled by the controller 11 via a drive control device (not shown).

Two or four of photographic units 1 are typically provided. More photographic units 1 may be provided depending on the necessity.

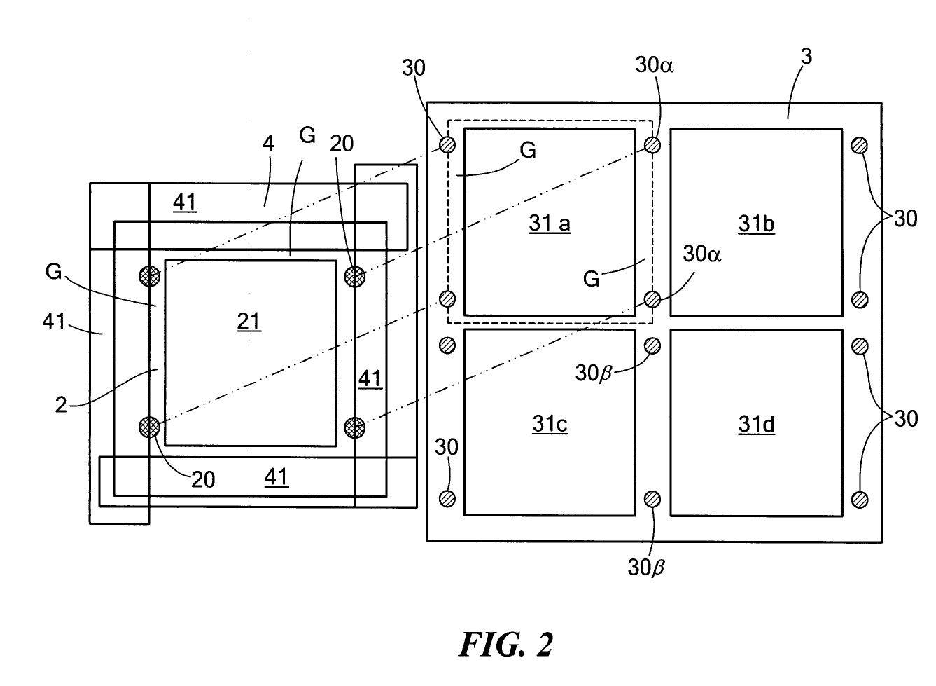

A mask shutter 4 is installed between the photo mask 2 and the exposure light source 71 as shown in FIG. 2 in order to mask around a circuit pattern 21 depicted on the photo mask 2 and to expose only the circuit pattern 21. The mask shutter 4 is movable by a mask shutter moving device 40 and controlled by the controller 11 to expose a certain part of the board 3.

FIG. 2 explains a relationship between the photo mask 2 and the printed circuit board 3. The photo mask 2 and the printed circuit board 3 are shown as side-by-side in FIG. 2 for purposes of illustration in spite of the fact that they are vertically separated as shown in FIG. 1. In the embodiment, the circuit patterns 21 of the photo mask 2 are to be exposed successively on four separate exposure areas 31 a, b, c, d of the printed circuit board 3.

The board marks 30 are set on four positions around the exposure areas 31a-31d. and the mask marks 20 are also set on four positions around the circuit pattern 21 corresponding to the separate exposure areas 31a-31d.

Two board marks 30a are placed between the separate exposure areas 31a and 31b and are used in common for the exposures of both the areas 31a and 31b. Two board marks 30β are similarly used for both the exposure areas 31c and 31d.

The mask shutter 4 (FIG. 1) has four rectangular shutter pieces 41 (FIG. 2), which are moved by the mask shutter moving device 40 and shields the area around the circuit pattern 21 from the exposure light so that light only passes through the circuit pattern 21; only that pattern's image can expose the separate exposure areas 31a-31d with the exposure light. However, the alignment accuracy of the shutter pieces 41 is limited, and a space G that is not masked appears around the circuit pattern 21. Around the divided exposure areas 31a-31d there appears also the space G that is unavoidably irradiated by the exposure rays. The mask marks 20 around the circuit pattern 21 and the board marks 30 at corresponding positions on the board 3 have part of or all of them inside of the space G that is not masked from the exposure light.

Thus the space G is also exposed and the board marks 30 are also illuminated when the exposure is conducted.

The board marks 30α,β are exposed in one exposure of the separate exposure areas 31a-31d, causing recognition accuracy of the board marks 30α,β to become worse, and the alignment accuracy becomes worse in the next alignment of the separate exposure areas 31a-31d.

For example, the exposure at the separate exposure area 31a exposes the board mark 30α, and the recognition accuracy of the board mark 30α becomes worse. The board mark 30α is used for aligning the next separate exposure area 31b with the photo mask 2, and the worsening recognition of the board mark 30α results in adversely affecting the accuracy of the alignment between the divided exposure area 31b and the photo mask 2.

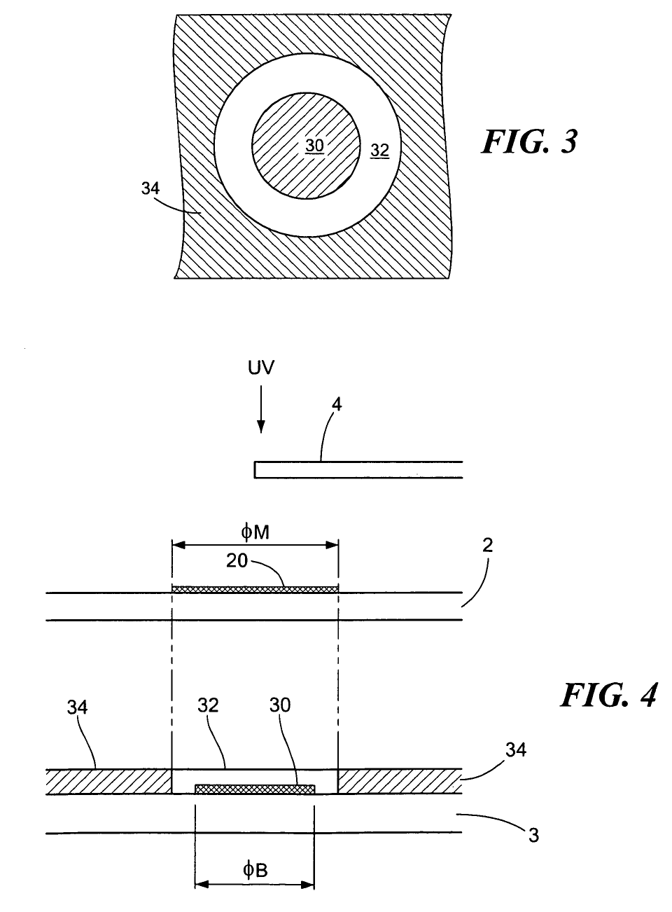

In the embodiment of the invention shown in FIGS. 3 and 4, each position of the mask marks 20 overlap the corresponding positions of the board marks 30 during exposure, and the mask marks 20 are larger than the board marks 30 so as to shield each board mark 30 from the exposing light. In FIG. 4, a diameter ØM of the circular mask mark 20 is larger than a diameter ØB of the circular board mark 30.

The mask mark 20 includes a material which can shield marks 30 from the exposure light, and preferably the mask marks 20 have a shielding membrane or film made of metallic membrane or film such as chrome.

When the mask mark 20 is depicted under the condition of ØM>ØB, the mask mark 20 can shield the board mark 30 and the area around the board mark 30 from the exposure light as shown in FIG. 3, and a shield area 32 is formed in the exposing light after the alignment. The board mark 30 included in the shield area 32, and part of a photo resist portion 34 around the board mark 30 will not be exposed and the shield area 32 prevents a photosensitive reaction.

Accordingly, the problem that the recognition accuracy of the board mark 30 and the alignment accuracy in alignment become worse with use is eliminated.

The shapes of the mask marks 20 and the board marks 30 are arbitrary. They can be in any shape, such as a square or a circle, as long as the mask mark 20 can shield the board mark 30 from the exposure light in exposing procedure.

The typical full system operation will be described hereafter.

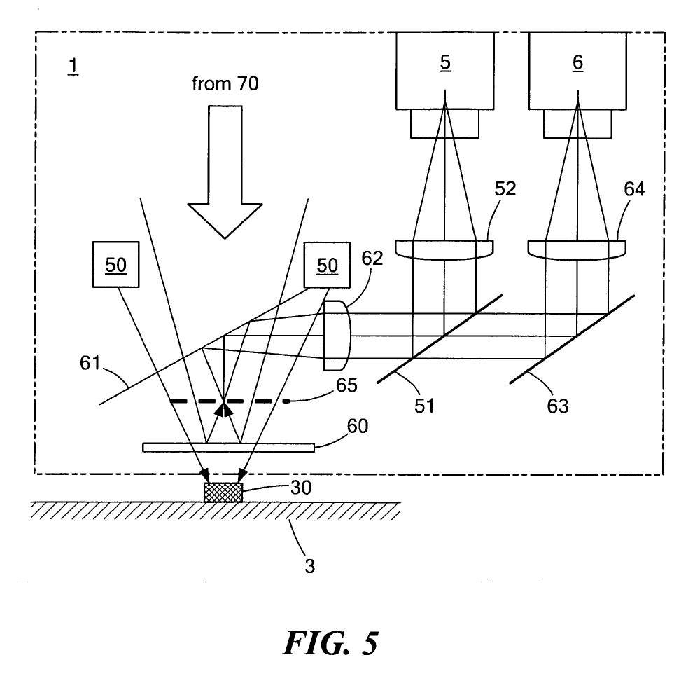

The mask shutter 4 is opened so as not to mask the mask mark 20 and to see the whole mask mark 20. Then the mask mark 20 and the board mark 30 of the separate exposure areas 31a-31d to be exposed are separately detected by the photographic unit 1 (FIGS. 1 and 5) and the printed circuit board 3 and/or photo mask 2 are moved and aligned in the X, Y Ø directions by the board stage 35 and/or mask stage 25 so as to make the position difference between the centers of the mask marks 20 and the board marks 30 smallest.

The photographic unit 1 can be similar to the one disclosed in Japanese laid open No. 2004-4215. As shown in FIG. 5, the photographic unit 1 includes a board mark CCD sensor 5 and a mask mark CCD sensor 6 that image the board mark 30 and the mask mark 20 respectively.

The mask mark 20 is irradiated by ultraviolet rays from the exposure light source 71 and directs the rays to projection lens 70 and through a half mirror 61. The rays are reflected from a surface 65 through semi-reflecting mirror 51 to a reflector 63 to the mask mark CCD 6 for sensing the mask mark 20 via image formation lenses 62 and 64. Surface 65 is an image formation surface.

In the alignment procedures, the ultraviolet reflector 60 shields the ultraviolet rays from the printed circuit board 3 and avoids any impact from the ultraviolet rays.

The board mark 30 is irradiated through mirror 61 by infrared rays or visible rays from a lighting device 50, and reflected rays bounce off half-mirror 61 and pass through lens 62. A beam splitter 51 reflects the rays from mirror 62 through an image formation lens 52 to the board mark CCD 5 that images the board mark 30.

The image data of the board mark 30 and the mask mark 20 detected by the board mark CCD 5 and the mask mark CCD 6 are transmitted to the image processor 10 where the data are processed, stored at a controller 11 and displayed at a display 12.

As mentioned above, the board stage 35 and/or mask stage 25 are moved in response to alignment data to make the position discrepancy between the board mark 30 and the mask mark 20 zero and align the photo mask 2 and the printed circuit board 3.

After the alignment is finished, the photographic unit 1 is moved out and the area around the circuit pattern 21 is masked by the mask shutter 4, then the sequence of the exposures at the separate exposure areas 31a-31d are performed by the exposure light source 71.

After finishing exposing one of the separate areas 31a-31d, the alignment for the next exposure area 31a-31d will be carried out before the exposure of that separate exposure area 31a-31d. Since the board marks 30a, used in common were masked by the mask mark 20 and positioned in the shield area 32 at the former exposure, and the board marks 30a, and the peripheral area were not exposed and the board marks 30a, were not discolored. Thus a high discrimination of the board marks 30a, and a high alignment accuracy can be maintained.

What is claimed is:

1. A projection exposure device having a light source for projecting light and a photo mask provided with a pattern to be projected on a target board to project said pattern of said photo mask on to a certain area of the board, the device comprising:
a mask mark for alignment provided with the photo mask;
a board mark for alignment provided with the board; and
an alignment device for aligning the photo mask relative to the board based on the mask mark and the board mark by separate photosensing thereof;
the projection of said mask mark onto said board overlapping the board mark; and
said mask mark being larger in projection than said board mark, whereby said mask mark shields said board mark from the projected light.

2. The projection exposure device of claim 1, wherein;
said board has plural ones of said certain areas and the projection of said pattern of said photo mask is executed to successively illuminating each of said plural certain areas of the board;
said board mark is plural for said plural certain areas and said mask mark is also plural for the plural board marks;
at least one or more of the board marks is utilized in common with said plurality of said certain area of the board;
one or more of mask marks corresponding to the board mark utilized in common is larger than the board mark and shields said board mark from the projected light.

3. The projection exposure device of claim 2, further comprising:
a mask shutter for shielding other of the areas than said one certain area among the plurality of said certain area of the board to be irradiated by the projected light, wherein:
a space not shielded by said mask shutter is illuminated around said certain area to be irradiated by the projected light;
at least part of said board mark utilized is included in said space.

4. The projection exposure device of claim 1, wherein:
A portion of said mask mark shielding said board mark from the projected light includes a shielding film made of a metal film.

5. A method of providing exposure light from a light source to project a photo mask pattern onto a target board to a certain area of the board, said method comprising the steps of:
photosensing separately a mask mark of the photo mask and a board mark for alignment;
aligning the photo mask and the board based on the photosensed mask mark and the board mark, by
overlapping said mask mark on said board mark wherein said mask mark is larger than said board mark, and said mask mark shields said board mark from the projected light.

6. The method of providing exposure of claim 5, wherein plural of said certain areas of the board are provided and said projection of said pattern of said photo mask is done successively against each of said areas of a plurality of certain areas of the board,
providing a board mark for each of said plural certain areas and providing a mask mark for each of the plural board marks;
utilizing at least one of the board marks in common with said plurality of said certain areas of the board; and wherein one or more of the mask marks corresponding to the board mark utilized in common is larger than the board mark and shields said board mark from the projected light.

7. The method of providing exposure of claim 6, further comprising the steps of:
shielding by a mask shutter other areas than one certain area among the plurality of said certain areas of the board to be irradiated by the projected light, wherein:
a space not shielded by said mask shutter is formed around said certain area to be irradiated by the projected light; and
at least part of said board mark utilized in common is positioned on said space not shielded.
